(19) United States
(12) Patent Application Publication
(10) Pub. No.: US 2016/0104829 A1
(43) Pub. Date: Apr. 14, 2016

(54) THERMOELECTRIC CONVERSION ELEMENT AND THERMOELECTRIC CONVERSION MODULE

(71) Applicant: FUJIFILM Corporation, Tokyo (JP)

(72) Inventors: Naoyuki HAYASHI, Ashigara-kami-gun (JP); Eri TAKAHASHI, Ashigara-kami-gun (JP)

(73) Assignee: FUJIFILM Corporation, Tokyo (JP)

(21) Appl. No.: 14/971,090

(22) Filed: Dec. 16, 2015

Related U.S. Application Data
(63) Continuation of application No. PCT/JP2014/064865, filed on Jun. 4, 2014.

(30) Foreign Application Priority Data
Jul. 1, 2013 (JP) 2013-138167

(51) Int. Cl. H01L 35/32; H01L 35/08

(52) U.S. Cl. CPC H01L 35/32; H01L 35/08

(57) ABSTRACT

Provided are a thermoelectric conversion element in which an electrode pair is formed on a substrate, an insulating layer is formed between the electrode pair, an n-type thermoelectric conversion layer containing an organic n-type thermoelectric conversion material is formed on one electrode, and a p-type thermoelectric conversion layer containing an organic p-type thermoelectric conversion material is formed on the other electrode, while the n-type thermoelectric conversion layer and the p-type thermoelectric conversion layer have a separation region in which the two members are arranged apart by the insulating layer and a contact region formed thereabove, in which the two members are joined to each other; and a thermoelectric conversion module using this thermoelectric conversion element.

### CROSS REFERENCE TO RELATED APPLICATIONS

This application is a continuation of PCT International Application No. PCT/JP2014/064865 filed on Jun. 4, 2014, which claims priority under 35 U.S.C. §119(a) to Japanese Patent Application No. 2013-138167 filed on Jul. 1, 2013. Each of the above applications is hereby expressly incorporated by reference, in its entirety, into the present application.

### BACKGROUND OF THE INVENTION

1. Field of the Invention

The present invention relates to a thermoelectric conversion element and a thermoelectric conversion module using this thermoelectric conversion element.

2. Description of the Related Art

Thermoelectric conversion materials that can mutually convert thermal energy and electric energy are used in power generating elements that generate electricity by means of heat, and in thermoelectric conversion elements such as Peltier devices.

Thermoelectric conversion elements are advantageous in that the elements can directly convert heat energy to electric power, and the elements do not require any moving parts. Therefore, when power generating elements that utilize thermoelectric conversion elements are provided at sites where heat is exhausted, for example, in incinerating furnaces or various facilities of industrial plants, it is not necessary to incur operating costs, and electric power can be conveniently and easily obtained.

In regard to such thermoelectric conversion elements, among thermoelectric conversion elements that use inorganic materials as the thermoelectric conversion materials, a so-called π-type thermoelectric conversion element as described in JP5098589B is known.

A π-type thermoelectric conversion element has a configuration in which a pair of electrodes that are arranged apart from each other is provided, and an n-type thermoelectric conversion material is provided on one of the electrodes, while a p-type thermoelectric conversion material is provided on the other electrode, such that the thermoelectric conversion materials are similarly arranged apart from each other, with the top surfaces of the two thermoelectric conversion materials being connected via the electrodes.

Furthermore, a plurality of thermoelectric conversion elements are arranged such that the n-type thermoelectric conversion material and the p-type thermoelectric conversion material are alternately disposed, and the electrodes in a part underneath the thermoelectric conversion materials are connected in series. Thus, a thermoelectric conversion module is formed.

For example, JP5098589B proposes a thermoelectric conversion element (thermoelectric conversion module) formed using oxide thermoelectric conversion materials, by joining an n-type oxide thermoelectric conversion material and a p-type oxide thermoelectric conversion material, without using electrodes for the connection of top surfaces.

This thermoelectric conversion element has a configuration in which an insulating material such as glass is provided between the n-type oxide thermoelectric conversion material and the p-type oxide thermoelectric conversion material that are joined, and a region in which the two thermoelectric conversion materials are directly joined and a region in which the two thermoelectric conversion materials are joined via an insulating material such as glass are formed on the joining interface between the n-type oxide thermoelectric conversion material and the p-type oxide thermoelectric conversion material.

On the other hand, it may also be considered to obtain a thermoelectric conversion module having a reduced weight or having satisfactory flexibility, by using an organic material as the thermoelectric conversion material.

For instance, JP2010-199276A describes a thermoelectric conversion element (thermoelectric conversion module) formed by sequentially arranging an n-type thermoelectric conversion material (n-type semiconductor element), a p-type thermoelectric conversion material (p-type semiconductor element) and an insulator on a support, in which organic semiconductor materials are used as the thermoelectric conversion materials, and the n-type thermoelectric conversion material and the p-type thermoelectric conversion material, or the thermoelectric conversion materials together with the insulator, are formed by coating or printing.

### SUMMARY OF THE INVENTION

A thermoelectric conversion element can be produced even if only either one of an n-type thermoelectric conversion element and a p-type thermoelectric conversion element is used. However, when the power generation efficiency is considered, it is preferable to use both an n-type thermoelectric conversion element and a p-type thermoelectric conversion element, as in the case of the π-type thermoelectric conversion element described above.

Furthermore, as described above, when weight reduction, impartation of flexibility and the like are considered, it is preferable to use organic materials as the thermoelectric conversion materials.

However, a thermoelectric conversion element having satisfactory power generation efficiency, which uses an organic n-type thermoelectric conversion material and an organic p-type thermoelectric conversion material, has a configuration corresponding to the π-type element described above, and exhibits suppressed generation of a leak current between electrodes, has not yet been realized.

An object of the present invention is to solve such problems of the prior art technologies, and is to provide a thermoelectric conversion element realized by using a thermoelectric conversion element which has a configuration corresponding to the so-called π-type configuration that is utilized in thermoelectric conversion elements using inorganic materials, and has satisfactory power generation efficiency with suppressed generation of a leak current between electrodes, and by using an n-type thermoelectric conversion layer based on an organic n-type thermoelectric conversion material and a p-type thermoelectric conversion layer based on an organic p-type thermoelectric conversion material; and a thermoelectric conversion module which uses this thermoelectric conversion element.

In order to achieve such an object, the thermoelectric conversion element of the present invention provides a thermoelectric conversion element including:

a substrate;

a pair of electrodes formed to be arranged apart from each other on the surface of the substrate;

an insulating layer formed between the pair of electrodes so as to be in contact with the substrate and to cover the edges on the sides where the pair of electrodes face each other; and

a thermoelectric conversion layer composed of a p-type thermoelectric conversion layer containing an organic p-type thermoelectric conversion material, which is formed to cover at least a portion of one of the pair of electrodes, and an n-type thermoelectric conversion layer containing an organic n-type thermoelectric conversion material, which is formed to cover at least a portion of the other one of the pair of electrodes,

in which the p-type thermoelectric conversion layer and the n-type thermoelectric conversion layer have a separation region in which the thermoelectric conversion layers are arranged apart by the insulating layer, and a contact region in which the thermoelectric conversion layers are joined to each other in a part above the insulating layer.

In regard to such a thermoelectric conversion element of the invention, it is preferable that the thermal conductivity of the insulating layer is 1 W/(m·K) or less.

Furthermore, it is preferable that the substrate is formed from an organic material.

Furthermore, it is preferable that the insulating layer has a circular arc-shaped top surface.

Furthermore, it is preferable that the ratio between thicknesses of the insulating layer and the thermoelectric conversion layer satisfies the condition that “insulating layer/thermoelectric conversion layer=0.3 to 0.9”.

Furthermore, it is preferable that an electrode for connection that is brought into contact with the p-type thermoelectric conversion layer and the n-type thermoelectric conversion layer is provided on the two thermoelectric conversion layers.

It is also preferable that the p-type thermoelectric conversion layer and the n-type thermoelectric conversion layer contain carbon nanotubes and a binder.

Moreover, it is preferable that at least one of the p-type thermoelectric conversion layer and the n-type thermoelectric conversion layer is formed such that a portion thereof is brought into contact with the substrate.

Furthermore, the thermoelectric conversion module of the invention provides a thermoelectric conversion module having a plurality of thermoelectric conversion elements connected in series, the module being formed by arranging the thermoelectric conversion elements of the invention to be apart from each other such that the p-type thermoelectric conversion layer and the n-type thermoelectric conversion layer are alternately arranged, and

connecting the electrodes covered by the p-type thermoelectric conversion layers of adjacent thermoelectric conversion elements, to the electrodes covered by the n-type thermoelectric conversion layers of adjacent thermoelectric conversion elements.

According to the invention as such, a thermoelectric conversion element which uses an n-type thermoelectric conversion layer based on an organic n-type thermoelectric conversion material and a p-type thermoelectric conversion layer based on an organic p-type thermoelectric conversion material, has a configuration corresponding to a so-called π-type configuration that is utilized in a thermoelectric conversion element using an inorganic material, and exhibits satisfactory power generation efficiency by suppressing the generation of a leak current between electrodes; and a thermoelectric conversion module exhibiting satisfactory power generation efficiency, which uses this thermoelectric conversion element, can be obtained.

### BRIEF DESCRIPTION OF THE DRAWINGS

FIG. 1(A) is a front view diagram conceptually illustrating an example of a thermoelectric conversion element of the invention; FIG. 1(B) is a plan view diagram conceptually illustrating an example of the thermoelectric conversion element of the invention; and FIG. 1(C) is a plan view diagram conceptually illustrating another example of the thermoelectric conversion element of the invention.

FIG. 2(A) to FIG. 2(D) are conceptual diagrams for explaining examples of the methods for producing the thermoelectric conversion elements illustrated in FIG. 1(A) and FIG. 1(B).

FIG. 3 is a front view diagram conceptually illustrating another example of the thermoelectric conversion element of the invention.

FIG. 4 is a front view diagram conceptually illustrating an example of a thermoelectric conversion module of the invention.

FIG. 5 is a plan view diagram conceptually illustrating the thermoelectric conversion module according to an embodiment.

### DESCRIPTION OF THE PREFERRED EMBODIMENTS

Hereinafter, a thermoelectric conversion element and a thermoelectric conversion module of the invention will be explained in detail, based on suitable embodiments illustrated in the attached drawings.

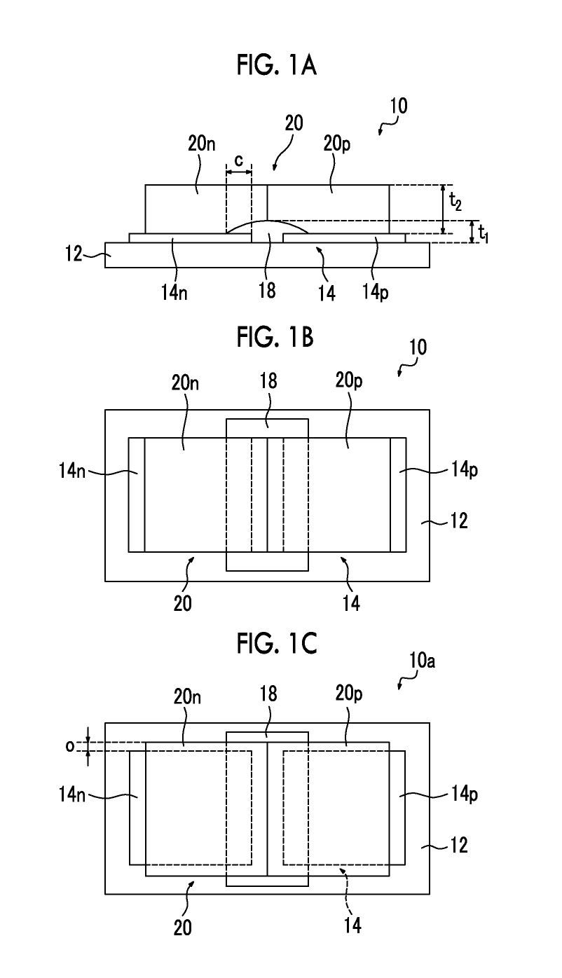

FIG. 1(A) and FIG. 1(B) conceptually illustrate an example of the thermoelectric conversion element of the invention. Meanwhile, FIG. 1(A) is a front view diagram, and FIG. 1(B) is a plan view diagram.

The thermoelectric conversion element 10 illustrated in FIG. 1(A) and FIG. 1(B) is basically configured to include a substrate 12; an electrode pair 14 (a pair of electrodes) composed of a first electrode 14n and a second electrode 14p; an insulating layer 18; and a thermoelectric conversion layer 20 composed of an n-type thermoelectric conversion layer 20n and a p-type thermoelectric conversion layer 20p.

Here, in regard to the thermoelectric conversion element 10 of the invention, the n-type thermoelectric conversion layer 20n uses an organic n-type thermoelectric conversion material as the thermoelectric conversion material, and the p-type thermoelectric conversion layer 20p uses an organic p-type thermoelectric conversion material as the thermoelectric conversion material.

As illustrated in FIG. 1(A), in the thermoelectric conversion element 10, the electrode pair 14 composed of the first electrode 14n and the second electrode 14p that are arranged apart is formed on the surface of the substrate 12.

In the following, for convenience, the direction of separation between the first electrode 14n and the second electrode 14p (horizontal direction in FIG. 1) is referred to as a direction of arrangement. Furthermore, a direction perpendicularly intersecting this direction of arrangement (a direction perpendicular to the paper plane of FIG. 1(A), the vertical direction in FIG. 1(B)) is also referred to as the width direction. Also, with respect to the electrode pair 14, the side facing the substrate 12 (upper side in FIG. 1(A)) is referred to as the top, and the other side is referred to as the bottom.

On the substrate 12 between the first electrode 14n and the second electrode 14p, an insulating layer 18 is formed so as to embed the gap between the electrode pair 14 and to cover the edges of the sides where the first electrode 14n and the second electrode 14p face each other.

On the first electrode 14n, an n-type thermoelectric conversion layer 20n is formed, other than on the edge of the side opposite to the insulating layer 18 in the direction of arrangement. On the other hand, on the second electrode 14p, a p-type thermoelectric conversion layer 20p is similarly formed, except for the edge of the opposite side of the insulating layer 18 in the direction of arrangement.

The n-type thermoelectric conversion layer 20n and the p-type thermoelectric conversion layer 20p that constitute the thermoelectric conversion layer 20 are both formed over the top of the insulating layer 18 and are joined at the center in the direction of arrangement on the insulating layer 18. Therefore, on the joining interface (facing surfaces) of the n-type thermoelectric conversion layer 20n and the p-type thermoelectric conversion layer 20p, there exists a separation region in which the thermoelectric conversion layers are arranged apart by the insulating layer 18, and present thereon is a contact region in which the two layers are directly joined.

In such a thermoelectric conversion element 10, for example, a temperature difference occurs between the top and the bottom as a result of heating by contact with a heat source or the like, and thus a difference in the carrier density occurs between the top and the bottom due to this temperature difference, thereby electric power being generated.

Meanwhile, according to the invention, a configuration in which any of the top or the bottom is located on the heat source side can also be utilized.

In regard to the thermoelectric conversion element 10 of the invention, for the material for forming the substrate 12, various materials can be utilized as long as the materials have insulating surfaces (at least the surface on which the first electrode 14n and the like are formed), such as a plastic film, and an aluminum sheet obtained by forming an anodic oxide coating on the surface.

Regarding the material for forming the substrate 12, preferably, an organic material such as a plastic film is used. When the substrate 12 is formed from an organic material, it is preferable from the viewpoint that a thermoelectric, conversion element 10 having flexibility (that is, a thermoelectric conversion module having flexibility) can be formed, the weight of the thermoelectric conversion element 10 can be reduced, the thermoelectric conversion element 10 can be mounted directly on a curved surface of a pipe or the like, and damage caused by impacts can be prevented.

Furthermore, when the substrate 12 (at least the surface of the substrate 12) is formed from an organic material, it is also preferable from the viewpoint that the adhesiveness between the thermoelectric conversion layer 20 and the electrode pair 14 can be enhanced. In this regard, further detailed descriptions will be given below.

Regarding the organic material that can be utilized for the substrate 12, specifically, polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalene dicarboxylate; resin materials such as polyimide, polycarbonate, polypropylene, polyether sulfone, cycloolefin polymers, polyether ether ketone (PEEK), and triacetyl cellulose (TAC); epoxy glass, and liquid crystalline polyester are suitably utilized.

Regarding the material for forming the substrate 12, copolymers of these resin materials and mixtures of these materials can also be utilized.

Among them, from the viewpoints of easy availability and economic efficiency, as well as the viewpoint that dissolution by a solvent does not occur, and the formation of an insulating layer 18, an n-type thermoelectric conversion layer 20n and the like by means of coating or printing is enabled, preferred examples include polyethylene terephthalate, polyethylene naphthalate, polyimide, polyether ether ketone, epoxy glass, and liquid crystalline polyester. Among them, particularly suitable examples include polyethylene terephthalate, polyethylene naphthalate, polyimide, epoxy glass, and liquid crystalline polyester.

The thickness of the substrate 12 may be appropriately set depending on the strength, flexibility, weight, size and the like required for the thermoelectric conversion element 10.

Specifically, the thickness of the substrate 12 is preferably 5 μm to 1000 μm. Particularly, the thickness of the substrate 12 is more preferably 10 μm to 500 μm, and particularly preferably 10 μm to 250 μm, from the viewpoints of flexibility and weight reduction.

In regard to the thermoelectric conversion element 10 of the invention, an easy adhesion layer may be provided on the surface of the substrate 12 (the surface on which the insulating layer 18 or the like is formed, or on both surfaces). When an easy adhesion layer is provided on the surface of the substrate 12, it is preferable from the viewpoint that the adhesiveness between the electrode pair 14, the insulating layer 18, and the thermoelectric conversion layer 20 can be enhanced.

Regarding the easy adhesion layer, various materials which can increase adhesiveness can be utilized depending on the materials for forming the members to be formed on the substrate 12. Specific examples thereof include gelatin, polyvinyl alcohol (PVA), an acrylic resin, a urethane resin, and a polyester resin. Among them, preferred examples include an acrylic resin, a urethane resin, and a polyester resin.

The easy adhesion layer may also contain a crosslinking agent such as a carbodiimide crosslinking agent, an isocyanate crosslinking agent, and a melamine crosslinking agent.

Furthermore, if necessary, a plurality of easy adhesion layers may also be formed, as in the case of a two-layer configuration.

Regarding the method for forming the easy adhesion layer, various known film forming methods such as a coating method of applying a coating material that forms an easy adhesion layer, on the surface of the substrate 12 by a known method such as a bar coating method, and drying the coating material, can be utilized.

On the surface (main surface) of the substrate 12, an electrode pair 14 composed of a first electrode 14n and a second electrode 14p that are arranged apart from each other is formed. The direction of separation of the two electrodes is also referred to as the direction of arrangement, as described above.

In the thermoelectric conversion element 10, when this first electrode 14n and the second electrode 14p are connected with wiring, electric power (electric energy) generated by heating or the like is extracted. Furthermore, when a plurality of thermoelectric conversion elements 10 are aligned in the direction of arrangement, and the first electrodes 14n and the second electrodes 14p of adjacent thermoelectric conversion elements 10 are connected (formed into single sheets of electrodes), the thermoelectric conversion module of the invention is formed.

The interval (distance in the direction of arrangement) between the first electrode 14n and the second electrode 14p may be appropriately set according to the size or the like of the thermoelectric conversion element 10 to be formed.

Specifically, the interval is preferably 0.25 to 5 mm, and more preferably 0.5 to 4 mm.

When the interval between the electrodes is adjusted to this range, preferable results are obtained from the viewpoint that the space between the two electrodes can be filled with a sufficient amount of an insulating material, and the effect of having the insulating layer 18 can be reliably obtained, and the thickness of the insulating layer 18 can be easily controlled.

The size or thickness of each of the electrodes of the electrode pair 14 may be appropriately adjusted to a size by which the generated electric power can be reliably extracted without any loss, depending on the size or the like of the thermoelectric conversion element 10 to be formed.

Furthermore, in the examples illustrated in the diagrams, the various electrodes of the electrode pair 14 are all rectangular in shape; however, for the two electrodes, various shapes such as a circular shape can be utilized, in addition to a rectangular shape. Moreover, the two electrodes may have mutually different sizes, shapes, and the like.

Here, it is preferable that the first electrode 14n and the second electrode 14p have edges with a curvature, from the viewpoint that the prevention of leakage between electrodes and the reduction of electric discharge can be promoted.

Additionally, from the viewpoint that high electrical conductivity is obtained, and the adhesiveness between the electrodes and the substrate 12 can be enhanced, the thicknesses of the first electrode 14n and the second electrode 14p are each preferably 50 to 2000 nm.

Regarding the material for forming the electrode pair 14, various materials having the necessary electrical conductivity can be utilized.

Specific examples include metal materials such as copper, silver, gold, platinum, nickel, chromium, and copper alloys; and those materials that are utilized as transparent electrodes in various devices, such as indium tin oxide (ITO) and zinc oxide (ZnO). Among them, preferred examples include copper, gold, platinum, nickel, and copper alloys. Among them, more preferred examples include gold, platinum, and nickel.

Furthermore, the electrodes may have a configuration in which a plurality of electrodes are laminated together, such as a laminated structure of a chromium electrode and a gold electrode, in order to increase the adhesiveness of the electrodes that substantially extract electric power from the thermoelectric conversion layer and thereby output the power to the outside.

An insulating layer 18 is formed on the substrate 12 between the first electrode 14n and the second electrode 14p. Also, this insulating layer 18 is formed so as to cover the edges on the sides where the first electrode 14n and the second electrode 14p face each other.

Since the thermoelectric conversion element 10 of the invention has this insulating layer 18; a thermoelectric conversion element corresponding to a so-called π-type among those thermoelectric conversion elements which use inorganic thermoelectric conversion materials, can be obtained by using an organic n-type thermoelectric conversion material and an organic p-type thermoelectric conversion material. In this regard, detailed descriptions will be given below.

The insulating layer 18 is basically formed so as to cover the whole area between the first electrode 14n and the second electrode 14p on the substrate 12.

Furthermore, the insulating layer 18 may also be formed beyond the gap between the electrodes in the width direction, as illustrated in FIG. 1(B). When such a configuration is employed, it is preferable from the viewpoint that the coating of the electrode ends by the insulating layer 18 (insulating material) can be reliably achieved so that the insulating properties can be enhanced, the contact area between the insulating layer 18 and the substrate 12 can be increased, and the adhesiveness between the substrate 12 and the insulating layer 18 can be enhanced.

As described above, the insulating layer 18 is formed so as to cover not only the space between the electrodes but also the edges of the sides where the first electrode 14n and the second electrode 14p face each other (edges on the inner side in the direction of arrangement).

When such a configuration is employed, a thermoelectric conversion element 10 having more satisfactory power generation efficiency with a reduced leak current between the electrodes can be obtained. Furthermore, the adhesiveness between the electrode pair 14 and the thermoelectric conversion layer 20 that will be described below can be enhanced.

Preferably, the insulating layer 18 covers the edges on the sides where the first electrode 14n and the second electrode 14p face each other (hereinafter, also simply referred to as “facing edges”) over the entire area in the width direction.

On the other hand, it is desirable that the coating width c of the facing edges of the first electrode 14n and the second electrode 14p formed by the insulating layer 18 in the direction of arrangement are such that the insulating layer 18 covers also a small portion of the top surface of the electrodes at the facing edges (in the vicinity of the edges).

Here, according to the investigation of the present inventors, the coating width c of the electrodes forming by the insulating layer 18 in the direction of arrangement at these facing edges is preferably 0.05 to 2 mm, and more preferably 0.5 to 1 mm.

When the coating width c is adjusted to this range, preferable results are obtained from the viewpoint that the leakage between the electrodes can be more reliably suppressed, the adhesiveness between the electrode pair 14 and the thermoelectric conversion layer 20 can be further enhanced, and the contact area between the electrode pair 14 and the thermoelectric conversion layer 20 can be appropriately secured.

The thickness t₁ of the insulating layer 18 (thickness (height) from the substrate 12 in the vertical direction with respect to the surface of the substrate 12) may be appropriately set depending on the thickness of the electrode pair 14, the size of the thermoelectric conversion element 10, the thickness of the thermoelectric conversion layer 20 that will be described below, the interval between the first electrode 14n and the second electrode 14p, and the like.

Specifically, the thickness t₁ of the insulating layer 18 is preferably 0.02 μm to 10 mm, and more preferably 0.1 to 3 mm. When the thickness t₁ of the insulating layer 18 is adjusted to this range, preferable results are obtained from the viewpoint that the effect of having the insulating layer 18 can be more suitably obtained, and the like.

Here, as will be described below, it is preferable that the insulating layer 18 has a circular arc-shaped top surface as described above, and even if the top surface is flat-shaped, there are occasions in which the thicknesses of the entire area may not be necessarily identical. In this case, it is preferable that at least the position at which the insulating layer 18 has the largest thickness has the aforementioned thickness, and it is more preferable that the entire area has the aforementioned thickness. Also, in this case, it is preferable that the position at which the insulating layer 18 has the largest thickness is close to the center in the direction of arrangement between the first electrode 14n and the second electrode 14p, and it is particularly preferable that the relevant position is located at the center in the direction of arrangement.

Meanwhile, in regard to the thermoelectric conversion element 10 of the invention, the insulating layer 18 needs to be thicker (higher) than at least the electrode pair 14.

Regarding the shape of the top surface of the insulating layer 18 in the direction of arrangement, various shapes such as a flat shape (rectangular shape) and a triangular shape can be utilized in addition to the circular arc shape such as the illustrated example.

However, from the viewpoint that the packing ratio of the thermoelectric conversion layer at the interfaces between the insulating layer 18 and the electrodes can be increased, and thereby an enhancement in the adhesiveness between the electrodes and the thermoelectric conversion layer or an increase in the amount of power generation can be promoted, the shape of the top surface of the insulating layer 18 is preferably a circular arc shape such as the illustrated example.

Regarding the material for forming the insulating layer 18, various materials can be utilized as long as they have sufficient insulating properties.

Specific preferred examples thereof include inorganic materials such as glass (silicon oxide), alumina, and titanium dioxide; organic materials such as an olefin resin, an epoxy resin, an acrylic resin, and a polyimide; and hybrid materials of these inorganic materials and organic materials.

The materials for forming the insulating layer 18 is preferably a material having a thermal conductivity of 1 W/(m·K) or less, and more preferably a material having a thermal conductivity of 0.5 W/(m·K) or less.

As is well known, in a thermoelectric conversion element, as the temperature difference in the direction of movement of the carriers in the thermoelectric conversion layer becomes larger, a larger quantity of electric power can be generated. That is, in the thermoelectric conversion element 10 of the invention, as the temperature difference in the vertical direction (direction of separation between the top surface of the thermoelectric conversion layer 20 and the electrode pair 14) becomes larger, a larger quantity of electric power can be generated.

Therefore, by adjusting the thermal conductivity of the insulating layer 18 to the range described above, for example, when the top surface side of the thermoelectric conversion layer 20 is brought to a high temperature, heat being transferred to the side of the electrode pair 14 can be prevented. As a result, the temperature difference in the direction of separation between the top surface of the thermoelectric conversion layer 20 and the electrode pair 14 can be maintained, and thereby a larger quantity of electric power can be stably generated.

Regarding the material having such a thermal conductivity, the organic materials described above, such as an olefin resin, an epoxy resin, an acrylic resin, and a polyimide, may be listed as preferred examples of the material for forming the insulating layer 18. Among them, more preferred examples include an olefin resin, an epoxy resin, and a polyimide.

Furthermore, when the insulating layer 18 is formed from an organic material, an effect that high adhesiveness between the thermoelectric conversion layer 20 and the electrode pair 14 can be secured, may also be obtained.

As will be described in detail below, the thermoelectric conversion layer 20 basically has a configuration in which organic thermoelectric conversion materials (an organic n-type thermoelectric conversion material and an organic p-type thermoelectric conversion material) are dispersed in a binder. That is, according to the invention, the thermoelectric conversion layer 20 is a layer formed from organic materials (a layer containing organic materials as main components).

As is well known, a metal material and an organic material have poor adhesiveness. That is, the electrode pair 14 formed from metal materials and the thermoelectric conversion layer 20 formed from organic materials have poor adhesiveness.

Here, when the weight reduction and flexibility of the thermoelectric conversion element and the thermoelectric conversion module are considered, as discussed above, it is preferable that the substrate 12 in the thermoelectric conversion element 10 of the invention is formed from a plastic film.

Therefore, by forming the insulating layer 18 from an organic material, high adhesiveness between the substrate 12 and the insulating layer 18 is obtained. Also, by forming the insulating layer 18 from an organic material, high adhesiveness between the insulating layer 18 and the thermoelectric conversion layer 20 is obtained. As a result, the thermoelectric conversion layer 20 and the substrate 12 can be formed to have high adhesiveness therebetween by interposing the insulating layer 18 therebetween, and thereby, high adhesiveness between the thermoelectric conversion layer 20 and the electrode pair 14 can be secured. That is, it is preferable for the thermoelectric conversion element 10 of the invention that both the substrate 12 and the insulating layer 18 are formed from organic materials.

Meanwhile, in regard to the thermoelectric conversion element 10 of the invention, even in a case in which the substrate 12 and/or insulating layer 18 is not formed from an organic material, it is still acceptable to increase the adhesiveness between the electrode pair 14 and the thermoelectric conversion layer 20 by known methods including various surface treatments such as coating of a primer and a plasma treatment, and surface roughening treatments.

On the first electrode 14n, the n-type thermoelectric conversion layer 20n is formed, other than on the edge on the side opposite to the insulating layer 18 in the direction of arrangement. On the other hand, on the second electrode 14p, the p-type thermoelectric conversion layer 20p is similarly formed, except for the edge on the opposite side of the insulating layer 18 in the direction of arrangement.

As illustrated in FIG. 1, the n-type thermoelectric conversion layer 20n and the p-type thermoelectric conversion layer 20p are both formed over the top of the insulating layer 18, and in the illustrated example, the thermoelectric conversion layers are joined at the center in the direction of arrangement on the insulating layer 18. Therefore, in regard to the thermoelectric conversion layer 20, on the facing surfaces (joining interface) of the n-type thermoelectric conversion layer 20n and the p-type thermoelectric conversion layer 20p, there exists a separation region in which the thermoelectric conversion layers are separated by the insulating layer 18, and present thereon is a contact region in which the two thermoelectric conversion layers are directly joined.

In regard to the thermoelectric conversion element 10 illustrated in FIG. 1, according to a preferred embodiment, the n-type thermoelectric conversion layer 20n and the p-type thermoelectric conversion layer 20p are joined at the center in the direction of arrangement on the insulating layer 18, and the joined surface extends vertically with respect to the substrate 12. However, as for the thermoelectric conversion element of the invention, various configurations can be utilized in addition to the configuration illustrated in FIG. 1.

For example, in addition to the center in the direction of arrangement, the joining interface between the n-type thermoelectric conversion layer 20n and the p-type thermoelectric conversion layer 20p may be formed at a position on the side of the first electrode 14n or on the side of the second electrode 14p, rather than the center. That is, according to the invention, the joining interface between the n-type thermoelectric conversion layer 20n and the p-type thermoelectric conversion layer 20p may be such that the lower end of the contact region exists on the insulating layer 18. Meanwhile, when the prevention of leakage from the n-type thermoelectric conversion layer 20n to the second electrode 14p, or the prevention of leakage from the p-type thermoelectric conversion layer 20p to the first electrode 14n is considered, it is preferable that the joining interface (particularly, the lower end of the contact region) between the n-type thermoelectric conversion layer 20n and the p-type thermoelectric conversion layer 20p is close to the center in the direction of arrangement of the insulating layer 18, and it is particularly preferable that the joining interface is at the center in the direction of arrangement.

The joining interface between the n-type thermoelectric conversion layer 20n and the p-type thermoelectric conversion layer 20p may also be formed not to be parallel to a line normal to the substrate 12, but to form an angle with respect to a vertical line from the substrate 12. In addition, the joining interface between the n-type thermoelectric conversion layer 20n and the p-type thermoelectric conversion layer 20p may have a curved shape, a corrugated shape or the like, instead of a linear shape (flat shape).

In between the n-type thermoelectric conversion layer 20n and the p-type thermoelectric conversion layer 20p, there may exist a clear interface between the two layers as shown by the illustrated example, or a mixed region in which the components of the n-type thermoelectric conversion layer 20n and the components of the p-type thermoelectric conversion layer 20p are mixed may exist (exist in a mixture).

As such, the thermoelectric conversion element 10 of the invention includes the electrode pair 14 composed of the first electrode 14n and the second electrode 14p that are disposed to be apart, and the insulating layer 18 that embeds the gap between the two electrodes by covering the edges on the sides where the electrodes face each other, and above this electrode pair 14 and insulating layer 18, the thermoelectric conversion element 10 includes a thermoelectric conversion layer 20 composed of the n-type thermoelectric conversion layer 20n and the p-type thermoelectric conversion layer 20p that are joined together.

Since the present invention has such a configuration, a thermoelectric conversion element having a configuration corresponding to a so-called π-type among those thermoelectric conversion elements that use inorganic thermoelectric conversion materials, and having satisfactory power generation efficiency with suppressed occurrence of a leak current between the electrodes, is realized by using organic thermoelectric conversion materials.

As described above, in the thermoelectric conversion element 10, as the temperature difference between the heat source side and the opposite side becomes larger, a larger quantity of generated electric power can be obtained. In order to secure this temperature difference, it is preferable to set the distance between the edges of the heat source side and the opposite side to be larger. That is, according to the invention, it is necessary to sufficiently secure the distance (thickness) between the top surface of the thermoelectric conversion layer 20 and the electrode pair 14, and it is preferable to adjust the thermoelectric conversion layer 20 to have a thickness of a certain extent.

Regarding the method for forming a layer having a thickness of a certain extent using an organic material in an element having a size such as that of the thermoelectric conversion element 10, methods of performing printing or coating using a paste or coating material containing necessary components may be considered. Also, by using printing or coating, a thermoelectric conversion element (thermoelectric conversion module) can be produced at low cost with high productivity.

However, with regard to printing, it is very difficult to form a so-called π-type thermoelectric conversion element in which the n-type thermoelectric conversion material and the p-type thermoelectric conversion material are separated as in the case of using inorganic thermoelectric conversion materials.

In this regard, since the present invention has the configuration described above including the electrode pair 14, the insulating layer 18 and the like, the invention realizes a thermoelectric conversion element which has a configuration corresponding to a π-type having a separation region in which the n-type thermoelectric conversion layer 20n and the p-type thermoelectric conversion layer 20p are separated by the insulating layer 18, and having a contact region thereabove, at the facing surfaces between thermoelectric conversion layers, and which has satisfactory power generation efficiency with suppressed occurrence of a leak current between the electrodes.

In the thermoelectric conversion element 10 of the invention, the thermoelectric conversion layer 20 basically has a configuration in which organic thermoelectric conversion materials are dispersed in a binder.

The thickness t₂ (thickness (height) from the electrode pair 14 in a vertical direction with respect to the top surface of the substrate 12) of such a thermoelectric conversion layer 20 (n-type thermoelectric conversion layer 20n and p-type thermoelectric conversion layer 20p) may vary depending on the size of the thermoelectric conversion element 10, and the like, and any thickness which can secure a satisfactory temperature difference between the upper and lower surfaces and can obtain a required amount of power generation may be appropriately set.

Specifically, the thickness t₂ of the thermoelectric conversion layer 20 is preferably 0.05 μm to 30 mm, and more preferably 1 μm to 10 mm. When the thickness t₂ of the thermoelectric conversion layer 20 is adjusted to this thickness, preferable results are obtained from the viewpoint that a temperature difference between the top surface of the thermoelectric conversion layer 20 and the electrode pair 14 can be satisfactorily secured, and a large amount of power generation can be stably secured.

Here, there are occasions in which the thickness of the thermoelectric conversion layer 20 is not necessarily constant. Also, as will be described below, the top surface of the thermoelectric conversion layer 20 may have a circular arc shape or the like. In this case, it is preferable that at least the position at which the thermoelectric conversion layer 20 has the largest thickness has the aforementioned thickness, and it is more preferable that the entire area has the aforementioned thickness. Also, in this case, it is preferable that the position at which the thermoelectric conversion layer 20 has the largest thickness is closer to the center in the direction of arrangement between the first electrode 14n and the second electrode 14p, similarly to the case of the insulating layer 18, and it is particularly preferable that the relevant position is located at the center in the direction of arrangement.

In regard to the thermoelectric conversion element 10 of the invention, it is preferable that the ratio between the thickness t₁ of the insulating layer 18 and the thickness t₂ of the thermoelectric conversion layer 20, “t₁/t₂” is 0.3 to 0.9. That is, according to the invention, it is preferable that the ratio between the thicknesses of the insulating layer and the thermoelectric conversion layer is such that “insulating layer/thermoelectric conversion layer=t₁/t₂=0.3 to 0.9”.

As described above, the thermoelectric conversion element 10 of the invention includes a thermoelectric conversion layer 20 which is formed using organic materials as the thermoelectric conversion material, by joining an n-type thermoelectric conversion layer 20n and the p-type thermoelectric conversion layer 20p, with an insulating layer 18 interposed therebetween in a part underneath.

In regard to the thermoelectric conversion element 10 of the invention as such, the thickness of the contact region and the thickness of the separation region at the joining interface between the n-type thermoelectric conversion layer 20n and the p-type thermoelectric conversion layer 20p, that is, the thickness t₁ of the insulating layer 18 and the thickness t₂ of the thermoelectric conversion layer 20, affect the performance of the thermoelectric conversion element 10. Specifically, as the contact region becomes thicker, that is, as the thickness t₁ of the insulating layer 18 becomes thinner compared to the thickness t₂ of the thermoelectric conversion layer 20, the current increases, and the voltage decreases. On the contrary, as the separation region becomes thicker, that is, the thickness t₁ becomes thicker compared to the thickness t₂, the voltage increases, and the current decreases.

In consideration of this point, according to the present invention in which a thermoelectric conversion element 10 corresponding to a π-type is realized by the thermoelectric conversion layer 20 formed from organic materials, the ratio “t₁/t₂” is preferably 0.3 to 0.9, and more preferably 0.5 to 0.8.

When the invention has such a configuration, preferable results are obtained from the viewpoint that satisfactory electric power (electric energy) well-balanced between current and voltage can be outputted.

There are occasions in which the thicknesses of the insulating layer 18 and the thermoelectric conversion layer 20 are not necessarily constant.

In this case, regarding the thicknesses of the insulating layer 18 and the thermoelectric conversion layer 20, in both layers, the thickness at the position at which the layer has the largest thickness is designated as the thickness t₁ of the insulating layer 18 or the thickness t₂ of the thermoelectric conversion layer 20, and the ratio between the thickness t₁ of the insulating layer 18 and the thickness t₂ of the thermoelectric conversion layer 20, “t₁/t₂”, is calculated.

As described above, it is preferable that the joining interface between the n-type thermoelectric conversion layer 20n and the p-type thermoelectric conversion layer 20p is located in the vicinity of the center (at the center) in the direction of arrangement of the insulating layer 18. Furthermore, it is preferable that the positions at which the insulating layer 18 and the thermoelectric conversion layer 20 respectively have the largest thickness are located in the vicinity of the center (at the center) in the direction of arrangement of the electrode pair 14. Therefore, according to the invention, it is preferable that the positions at which the insulating layer 18 and the thermoelectric conversion layer 20 respectively have the largest thickness in the direction of arrangement are closer to the joining interface between the n-type thermoelectric conversion layer 20n and the p-type thermoelectric conversion layer 20p, and it is particularly preferable that the positions coincide with this joining interface.

In regard to the thermoelectric conversion element 10 of the invention, for the shape of the top surfaces of the n-type thermoelectric conversion layer 20n and the p-type thermoelectric conversion layer 20p, various shapes such as a circular arc shape and a curved surface shape can be utilized in addition to the flat shape such as the illustrated example.

In regard to the thermoelectric conversion element 10 of the invention, the planar shape (that is, the shape illustrated in FIG. 1(B)) and the size of the n-type thermoelectric conversion layer 20n and the p-type thermoelectric conversion layer 20p may be appropriately set according to the size, shape and the like of the electrode pair 14. Therefore, regarding the shape, various shapes such as a circular shape can be utilized in addition to the rectangular shape of the illustrated example.

Furthermore, the length over which the thermoelectric conversion layer 20 does not cover the electrode pair 14 in the direction of arrangement (length of exposure in the direction of arrangement of each electrode) at the edge on the side opposite to the insulating layer 18, may be appropriately set to a length at which the wiring for extracting the electric power generated by the thermoelectric conversion element 10 can be reliably secured, and the length in the direction of arrangement of the thermoelectric conversion element 10 does not become unnecessarily long. Specifically, the length is preferably 0.2 to 5 mm.

In the configuration illustrated in FIG. 1(B), the size in the width direction of the thermoelectric conversion layer 20 (n-type thermoelectric conversion layer 20n and the p-type thermoelectric conversion layer 20p) is the same as that of the electrode pair 14.

However, in addition to this, it is also preferable for the present invention that the thermoelectric conversion layer 20 is formed beyond the electrode pair 14 in the width direction, as in the case of the thermoelectric conversion element 10a illustrated in FIG. 1(C).

As described above, the substrate 12 is preferably formed of an organic material. Therefore, when the thermoelectric conversion layer 20 is formed beyond the electrode pair 14 in the width direction as such, the substrate 12 and the thermoelectric conversion layer 20 can be brought into direct contact, and an adhesive force can be obtained even in this contact region. As a result, the adhesive force between the thermoelectric conversion layer 20 and the electrode pair 14 can be further enhanced.

The width o of the thermoelectric conversion layer 20 that is formed beyond the electrode pair 14 in the width direction (contact width o) may be appropriately set according to the sizes in the width direction of the substrate 12 and the electrode pair 14, and the like.

Specifically, this width o is preferably 0.2 to 5 mm, and more preferably 2 to 5 mm. When the width o is adjusted to the range described above, preferable results are obtained from the viewpoint that a more suitable adhesive force between the thermoelectric conversion layer 20 and the electrode pair 14 as well as the substrate 12 is obtained.

Meanwhile, the contact between the substrate 12 and the thermoelectric conversion layer 20 may be implemented on both sides in the width direction of both the n-type thermoelectric conversion layer 20n and the p-type thermoelectric conversion layer 20p as illustrated in FIG. 1(C), and in addition to that, the contact may also be implemented at only any one of the n-type thermoelectric conversion layer 20n and the p-type thermoelectric conversion layer 20p, or may be implemented only on one end in the width direction.

The n-type thermoelectric conversion layer 20n is basically configured to include an organic n-type thermoelectric conversion material and a binder.

The p-type thermoelectric conversion layer 20p is basically configured to include an organic p-type thermoelectric conversion material and a binder.

Regarding the organic n-type thermoelectric conversion material (organic n-type semiconductor material), various known materials can be utilized.

For example, low molecular weight organic materials such as a naphthalene bisimide derivative, a perylene bisimide derivative, a phenanthroline derivative, a fluorinated phthalocyanine derivative, a fluorinated porphyrin derivative, a fluorinated pentacene derivative, and a fullerene derivative can be utilized.

Furthermore, polymeric organic materials such as a boron-doped polymer represented by the following formula (BORAMER T01 (trade name) manufactured by TDA Research, Inc.):

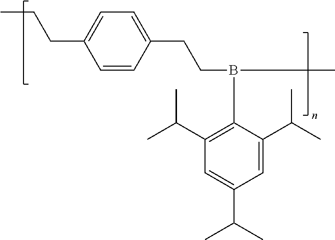

a boron-doped polymer represented by the following formula (BORAMER TC03 (trade name) manufactured by TDA Research, Inc.):

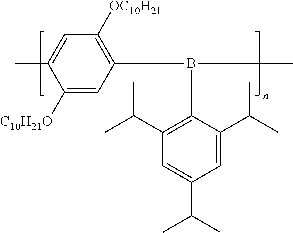

polyphenylenevinylenes having cyano groups as represented by the following formulas:

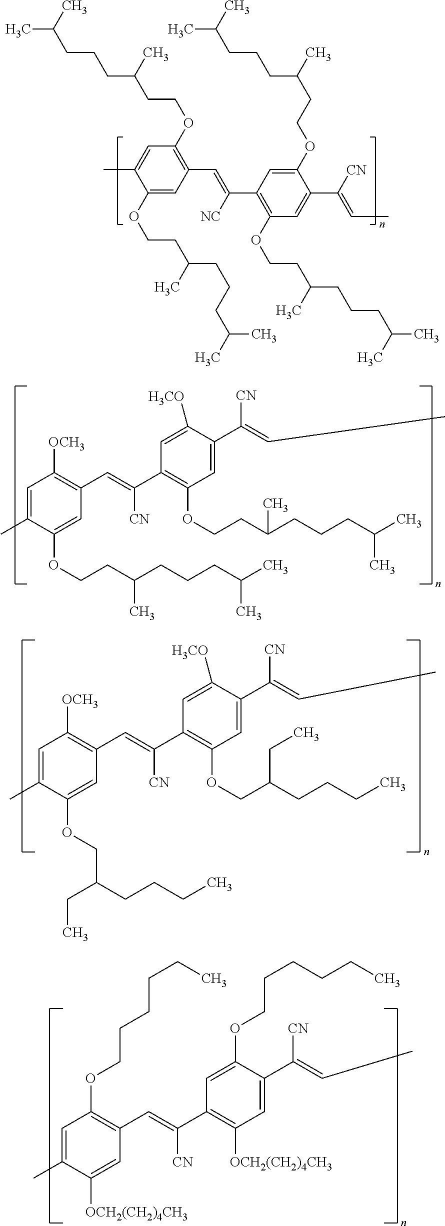

and a poly(benzimidazobenzophenanthroline) represented by the following formula:

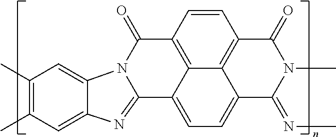

can be utilized.

Furthermore, charge-transfer complexes such as tetrathiafulvalene-tetracyanoquinodimethane (TTF-TCNQ) can also be utilized.

Among them, suitable examples of a more preferred organic n-type thermoelectric conversion material include n-type semiconductor materials obtained by mixing single-layer carbon nanotubes or multilayer carbon nanotubes with donors. Among them, in particular, a more suitable example is an n-type semiconductor material obtained by mixing single-layer carbon nanotubes with a donor. This material is preferably utilized from the viewpoint that high electrical conductivity is obtained.

Regarding the donor material, known materials such as alkali metals, hydrazine derivatives, metal hydrides (sodium borohydride, tetrabutylammonium borohydride, and lithium aluminum hydride), and polyethyleneimine can be utilized. Among them, polyethyleneimine is used as a preferable example from the viewpoint of the stability of the material and the like.

The single-layer carbon nanotubes may be modified or treated:

Examples of the method for modification or treatment include a method of incorporating a ferrocene derivative or a nitrogen-substituted fullerene (azafullerene); a method of doping an alkali metal (K) or a metal element (In or the like) into carbon nanotubes by an ion doping method; and a method of heating carbon nanotubes in a vacuum.

Examples of the organic p-type thermoelectric conversion material (organic p-type semiconductor material) include known π-conjugated polymers such as polyaniline, polyphenylenevinylene, polypyrrole, polythiophene, polyfluorene, acetylene, and polyphenylene.

Among them, suitable examples of a more preferred organic p-type thermoelectric conversion material include p-type semiconductor materials obtained by mixing single-layer carbon nanotubes or multilayer carbon nanotubes with an acceptor. Among them, in particular, a more suitable example is a p-type semiconductor material obtained by mixing single-layer carbon nanotubes with an acceptor. This material is preferably utilized from the viewpoint that high electrical conductivity is obtained.

Examples of the acceptor material include known materials including halogens such as iodine and bromine; Lewis acids such as PF₅ and AsF₅; protic acids such as hydrochloric acid and sulfuric acid; transition metal halides such as FeCl₃ and SnCl₄; and organic electron-accepting materials such as a tetracyanoquinodimethane (TCNQ) derivative and a 2,3-dichloro-5,6-dicyano-p-benzoquinone (DDQ) derivative. Among them, from the viewpoints of the compatibility with carbon nanotubes, the stability (being nondegradable and nonvolatile) at room temperature, and the like, organic electron-accepting materials such as a TCNQ derivative and a DDQ derivative are used as suitable examples.

Meanwhile, in the case of utilizing carbon nanotubes as an organic thermoelectric conversion material without being limited to the n-type or the p-type, nanocarbon materials such as carbon nanohorns, carbon nanocoils, carbon nanobeads, graphite, graphene, and amorphous carbon may also be included in addition to single-layer carbon nanotubes and multilayer carbon nanotubes.

Regarding the binder that constitutes the n-type thermoelectric conversion layer 20n and the p-type thermoelectric conversion layer 20p, various known materials can be utilized.

Specific suitable examples include a styrene polymer, an acrylic polymer, polycarbonate, polyester, an epoxy resin, a siloxane polymer, polyvinyl alcohol, and gelatin.

In regard to the thermoelectric conversion element 10 of the invention, the ratio between the amounts of the binder and the thermoelectric conversion materials in the thermoelectric conversion layer 20 may be appropriately set according to the materials used, the thermoelectric conversion efficiency required, the viscosity or solid content concentration of the solution that affects printing, or the like.

Specifically, the mass ratio of “thermoelectric conversion material/binder” is preferably 90/10 to 10/90, and more preferably 75/25 to 40/60.

When the ratio between the amounts of the binder and the thermoelectric conversion materials is adjusted to the range described above, preferable results are obtained from the viewpoint of higher power generation efficiency, imparting printing suitability, and the like.

The n-type thermoelectric conversion layer 20n and the p-type thermoelectric conversion layer 20p may both include a crosslinking agent as necessary.

Specific examples of the crosslinking agent include known materials, such as silane compounds such as phenethyltrialkoxysilane, aminopropyltrialkoxysilane, glycidylpropyltrialkoxysilane, and tetraalkoxysilane; low molecular weight crosslinking agents such as trimethylolmelamine, a di(tri)amine derivative, a di(tri)glycidyl derivative, a di(tri)carboxylic acid derivative, and a di(tri)acrylate derivative; and polymeric crosslinking agents such as polyallylamine, polycarbodiimide, and a polycation. When the n-type thermoelectric conversion layer 20n and the p-type thermoelectric conversion layer 20p contain crosslinking agents, preferable results are obtained from the viewpoint that the membrane strength is increased, and contamination of the wiring material that will be described below can be prevented.

The n-type thermoelectric conversion layer 20n and the p-type thermoelectric conversion layer 20p may both include a dispersant, a surfactant, a lubricating agent, a thickener such as alumina or silica, and the like, if necessary.

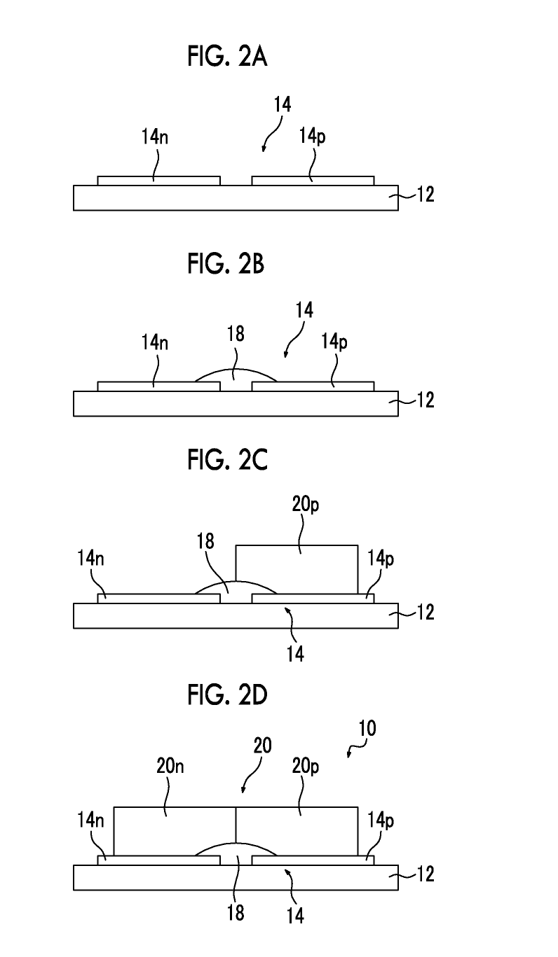

In the following, an example of the method for producing the thermoelectric conversion element 10 of the invention is described with reference to FIG. 2(A) to FIG. 2(D).

First, a substrate 12 such as described above is prepared, and as illustrated in FIG. 2(A), an electrode pair 14 composed of a first electrode 14n and the second electrode 14p is formed on the surface of the substrate.

Regarding the method for forming the electrode pair 14, various known methods for forming a metal film or the like can be utilized.

Specific examples include gas phase film forming methods (gas phase volumetric methods) such as an ion plating method, a sputtering method, a vacuum vapor deposition method, and a CVD method such as plasma CVD. Furthermore, the electrode pair may also be formed by forming micro particles of the aforementioned metal, and solidifying a metal paste containing a binder and a solvent.

Additionally, in regard to the thermoelectric conversion element 10 of the invention, after the electrodes are formed, if necessary, a surface modification treatment of the electrodes may be carried out for the purpose of enhancing the adhesiveness of the thermoelectric conversion layer 20 and the like.

Regarding the surface modification treatment, various known methods such as a corona treatment, a plasma treatment, and irradiation with UV-ozone can be utilized.

Next, as illustrated in FIG. 2(B), an insulating layer 18 is formed by embedding the gap between the first electrode 14n and the second electrode 14p and covering the facing edges of the electrode pair 14.

Regarding the method for forming the insulating layer 18, various known means can be utilized in accordance with the material for forming the insulating layer 18.

For example, when the insulating layer 18 is made of a polymer material such as an epoxy resin, a method of forming the insulating layer 18 by performing printing according to the shape of the insulating layer 18 to be formed, using a curable ink which forms a commercially available resin material or an organic material, by means of a screen printing machine or the like between the first electrode 14n and the second electrode 14p, and crosslinking the ink by irradiating the ink with ultraviolet radiation or by heating, may be employed.

Next, as illustrated in FIG. 2(C), a p-type thermoelectric conversion layer 20p is formed by covering the second electrode 14p and the insulating layer 18. Furthermore, as illustrated in FIG. 2(D), an n-type thermoelectric conversion layer 20n is formed so as to cover the first electrode 14n and the insulating layer 18, and to be joined to the p-type thermoelectric conversion layer 20p.

Meanwhile, the order of forming the p-type thermoelectric conversion layer 20p and the n-type thermoelectric conversion layer 20n may be reversed.

Regarding the method for forming the thermoelectric conversion layer 20 (p-type thermoelectric conversion layer 20p and n-type thermoelectric conversion layer 20n) as well, known methods can be utilized according to the organic thermoelectric conversion materials and binder used. For example, printing such as described above may be used.

First, pastes (inks) are respectively prepared by adding an organic thermoelectric conversion material and a binder as well as necessary components such as a dispersant to an organic solvent, and dispersing the components using a known method such as an ultrasonic homogenizer, a mechanical homogenizer, or a ball mill.

Regarding the dispersant, known materials such as anionic surfactants: sodium cholate, sodium dodecyl sulfate, sodium dodecyl benzenesulfonate, an alkylamine, a pyrene derivative, a porphyrin derivative, a π-conjugated polymer, and sodium polystyrene sulfonate can be used. Regarding the binder, known materials such as a styrene polymer, an acrylic polymer, polycarbonate, polyester, an epoxy resin, a siloxane polymer, polyvinyl alcohol, and gelatin can be used.

Examples of the organic solvent include known organic solvents such as an aromatic hydrocarbon solvent, an alcohol solvent, a ketone solvent, an aliphatic hydrocarbon solvent, an amide solvent, and a halogen solvent.

Specific examples of the aromatic hydrocarbon solvent include benzene, toluene, xylene, trimethylbenzene, tetramethylbenzene, cumene, ethylbenzene, methylpropylbenzene, methylisopropylbenzene, and tetrahydronaphthalene, and more preferred examples include xylene, cumene, trimethylbenzene, tetramethylbenzene, and tetrahydronaphthalene.

Examples of the alcohol solvent include methanol, ethanol, butanol, benzyl alcohol, and cyclohexanol, and more preferred examples include benzyl alcohol and cyclohexanol.

Examples of the ketone solvent include 1-octanone, 2-octanone, 1-nonanone, 2-nonanone, acetone, 4-heptanone, 1-hexanone, 2-hexanone, 2-butanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate, and more preferred examples include methyl isobutyl ketone and propylene carbonate.

Examples of the aliphatic hydrocarbon solvent include pentane, hexane, octane, and decane, and more preferred examples include octane and decane.

Examples of the amide solvent include N-methyl-2-pyrrolidone, N-ethyl-2-pyrrolidone, N,N-dimethylacetamide, N,N-dimethylformamide, and 1,3-dimethyl-2-imidazolidinone, and more preferred examples include N-methyl-2-pyrrolidone and 1,3-dimethyl-2-imidazolidinone.

Examples of the halogen solvent include chloroform, chlorobenzene, and dichlorobenzene, and more preferred examples include chlorobenzene and dichlorobenzene.

These solvents may be used singly or in combination of two or more kinds thereof.

When pastes are prepared as such, the p-type thermoelectric conversion layer 20p and the n-type thermoelectric conversion layer 20n are formed by printing the pastes according to the p-type thermoelectric conversion layer 20p and the n-type thermoelectric conversion layer 20n that are formed as described above, by a known printing method such as stencil printing, screen printing, ink jet printing, gravure printing, or flexographic printing, and drying the pastes by heating or the like.

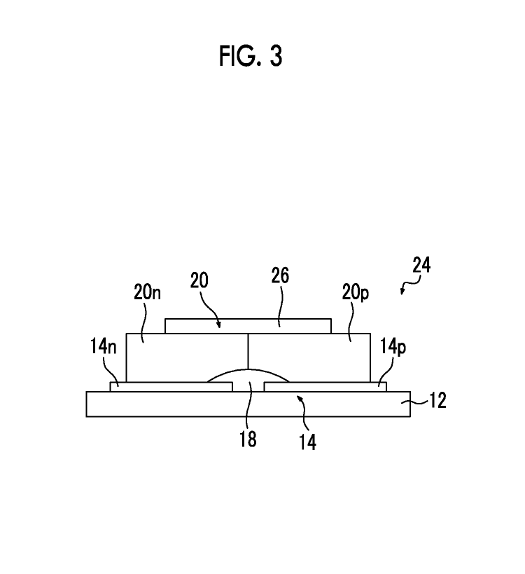

FIG. 3 illustrates an example of another embodiment of the thermoelectric conversion element of the invention.

Meanwhile, the thermoelectric conversion element 24 illustrated in FIG. 3 has the same configuration as that of the thermoelectric conversion element 10 illustrated in FIG. 1 described above, except for having a connection wiring 26 on the top surface, and therefore, the same reference numerals are assigned to the same members, while explanation is given mainly for different sites.

As illustrated in FIG. 3, the thermoelectric conversion element 24 has an electroconductive connection wiring 26 that electrically connects the p-type thermoelectric conversion layer 20p and the n-type thermoelectric conversion layer 20n to the top surface of the thermoelectric conversion layer 20.

As is well known, in regard to the p-type thermoelectric conversion layer 20p and the n-type thermoelectric conversion layer 20n formed from organic materials, there are occasions in which even if there is a connection region in which the two layers are brought into direct contact, sufficient electrical conductivity cannot be secured depending on cases.

On the contrary, the thermoelectric conversion element 24 illustrated in FIG. 3 has a connection wiring 26 that electrically connects the p-type thermoelectric conversion layer 20p and the n-type thermoelectric conversion layer 20n to the top surface of the thermoelectric conversion layer 20, as a preferred embodiment. Thereby, the thermoelectric conversion element 24 can secure sufficient electrical conductivity between the p-type thermoelectric conversion layer 20p and the n-type thermoelectric conversion layer 20n, and can achieve power generation with high efficiency.

Regarding the lengths and thicknesses in the direction of arrangement and the width direction of the connection wiring 26, any size that can secure sufficient electrical conductivity between the p-type thermoelectric conversion layer 20p and the n-type thermoelectric conversion layer 20n may be appropriately set.

Specifically, the length in the direction of arrangement of the connection wiring 26 is preferably 2 mm to 30 mm, and more preferably 3 mm to 20 mm. The length in the width direction is preferably 2 mm to 30 mm, and more preferably 3 mm to 20 mm.

When the size of the connection wiring 26 is adjusted to the aforementioned size, preferable results are obtained from the viewpoint that sufficient electrical conductivity between the p-type thermoelectric conversion layer 20p and the n-type thermoelectric conversion layer 20n can be secured more reliably.

Furthermore, regarding the material for forming the connection wiring 26, various known materials can be utilized.

For example, a material formed by dispersing electroconductive metal microparticles in a binder, such as a silver paste, may be used.

Furthermore, regarding the forming method with respect to the material for forming the connection wiring 26, various known methods such as the methods exemplified for the insulating layer 18 or the thermoelectric conversion layer 20 can be utilized.

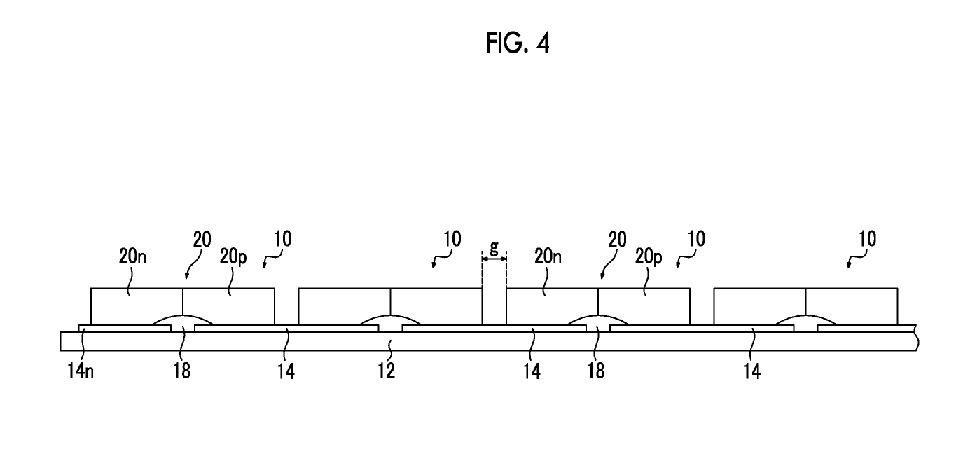

FIG. 4 conceptually illustrates an example of the thermoelectric conversion module of the invention.

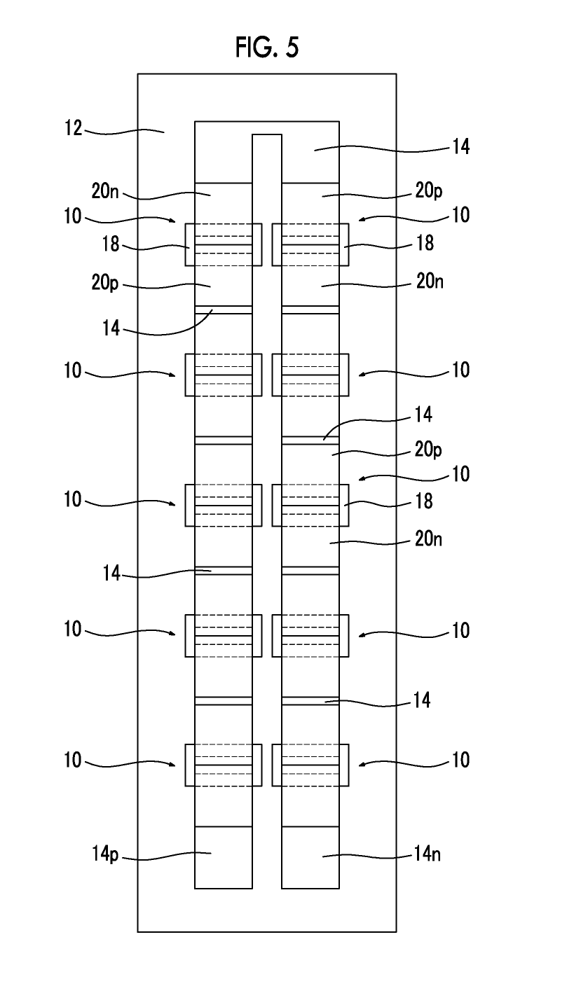

The thermoelectric conversion module of the invention has a plurality of thermoelectric conversion elements connected in series, by arranging the aforementioned thermoelectric conversion elements 10 in the direction of arrangement to be apart from each other such that the n-type thermoelectric conversion layer 20n and the p-type thermoelectric conversion layer 20p are alternately arranged, and connecting the second electrode 14p and the first electrode 14n in adjacent thermoelectric conversion elements 10 (see FIG. 5). That is, in the thermoelectric conversion module of the invention, adjacent thermoelectric conversion elements 10 have an electrode pair 14 in common (in between adjacent thermoelectric conversion elements 10, the electrode pair 14 serves as both the second electrode 14p and the first electrode 14n).

Meanwhile, the order of arrangement of the n-type thermoelectric conversion layer 20n and the p-type thermoelectric conversion layer 20p may be an inverse order to that of the example illustrated in FIG. 4. Also, the thermoelectric conversion element 24 may also be used instead of the thermoelectric conversion element 10.

Here, in the thermoelectric conversion module of the invention, as illustrated in FIG. 4, adjacent thermoelectric conversion elements 10 are disposed to be apart.

When such a configuration is adopted, the various thermoelectric conversion elements 10 can be thermally insulated from each other in this space. As a result, it is easier to cause a temperature difference in the vertical direction of the thermoelectric conversion layer 20, and power generation based on highly efficient thermoelectric conversion can be achieved.

The gap g between adjacent thermoelectric conversion elements 10 may be appropriately set according to the size of the thermoelectric conversion module, the size of the thermoelectric conversion layer 20, the number of connections of the thermoelectric conversion elements 10, and the like.

Specifically, the gap is preferably 0.1 mm to 5 mm, and more preferably 0.5 mm to 4 mm.

When the gap g is adjusted to this range, preferable results are obtained from the viewpoint that the aforementioned thermal insulation effect can be reliably obtained, highly efficient power generation is enabled, and there is no unnecessary increase in the size of the thermoelectric conversion module.

Thus, the thermoelectric conversion element and thermoelectric conversion module of the invention have been explained in detail; however, it should be noted that the present invention is not intended to be limited to the examples described above, and various improvements or modifications may be carried out to the extent that the gist of the invention is maintained.

### EXAMPLES

Hereinafter, the present invention will be explained in more detail by way of specific examples of the invention.

A substrate and an electrode pair (first electrode and second electrode) that were commonly used in all examples were produced as follows.

<Production of Substrate>

A substrate of a polyethylene terephthalate (PET) film was formed by the following procedure.

First, a PET resin having an intrinsic viscosity of 0.66, which was polycondensed using germanium (Ge) as a catalyst, was dried to have a water content ratio of 50 ppm or less, and then the PET resin was melted in an extruder by setting the heater temperature to 280° C. to 300° C.

The molten PET resin was discharged through a die onto a chilled roll to which static electricity had been applied, and a non-crystalline base was obtained. The non-crystalline base thus obtained was stretched 3.3 times in the direction of progress of the base, and then was stretched 3.8 times in the width direction. Thus, a substrate of a PET film having a thickness of 188 μm was obtained.

<Formation of Easy Adhesion Layer>

While the substrate having a thickness of 180 μm that was produced as described above was conveyed at a speed of conveyance of 105 m/min, two easy adhesion layers were applied on both surfaces of the substrate by the following procedure.

First, the substrate was subjected to a corona discharge treatment under the conditions of 730 J/m², and then a first layer coating liquid such as described below was applied thereon by a bar coating method. This first coating liquid was dried at 180° C. for 1 minute, and thus a first layer was formed. Thereafter, subsequently, a second coating liquid such as described below was applied in an amount of coating of 96.25 mg/m² on the first layers on both sides by a bar coating method, and then the second coating liquid was dried at 170° C. for 1 minute. Thereby, a PET film having a first easy adhesion layer and a second easy adhesion layer applied on both surfaces of the substrate was obtained.

(First Layer Coating Liquid)
Polyethylene-methacrylic acid copolymer binder: 23.3 parts by mass

(NUCREL N410 (trade name), manufactured by DuPont-Mitsui Polychemicals Co., Ltd.)
Colloidal silica: 15.4 parts by mass

(SNOWTEX R503 (trade name), manufactured by Nissan Chemical Industries, Ltd., solid content 20% by mass)
Epoxy monomer: 221.8 parts by mass

(DENACOL EX614B (trade name), manufactured by Nagase ChemteX Corporation, solid content 22% by mass)
Surfactant A: 19.5 parts by mass

(1 mass % aqueous solution of NAROACTY CL-95 (trade name), manufactured by Sanyo Chemical Industries, Ltd.)
Surfactant B: 7.7 parts by mass

(1 mass % aqueous solution of RAPISOL A-90 (trade name), manufactured by NOF Corporation.)
Distilled water: added to make up the whole amount to 1000 parts by mass

(Second Layer Coating Liquid)
Polyurethane binder: 22.8 parts by mass

(coating amount: 61.5 mg/m²)

(OLESTER UD-350 (trade name), manufactured by Mitsui Chemicals, Inc., solid content 38% by mass)

(SP value: 10.0, I/O value: 5.5)
Acrylic binder: 2.6 parts by mass

(coating amount: 5 mg/m²)

(EM48D (trade name), manufactured by Daicel Corporation, solid content 27.5% by mass)

(SP value: 9.5, I/O value: 2.5)
Carbodiimide compound: 4.7 parts by mass

(coating amount: 13.35 mg/m²)

(CARBODILITE V-02-L2 (trade name), manufactured by Nisshinbo Chemical, Inc., solid content 40% by mass)
Surfactant A: 15.5 parts by mass

(coating amount: 1.1 mg/m²)

(1 mass % aqueous solution of NAROACTY CL-95 (trade name), manufactured by Sanyo Chemical Industries, Ltd., nonionic)
Surfactant B: 12.7 parts by mass

(coating amount: 0.9 mg/m²)

(1 mass % aqueous solution of RAPISOL A-90 (trade name), manufactured by NOF Corporation, anionic)
Microparticles A: 3.5 parts by mass

(coating amount: 10 mg/m²)

(SNOWTEX XL (trade name), manufactured by Nissan Chemical Industries, Ltd., solid content 40.5% by mass)
Microparticles B: 1.6 parts by mass

(coating amount: 1.1 mg/m²)

(aqueous dispersion of AEROSIL OX-50 (trade name), manufactured by Nippon Aerosil Co., Ltd., solid content 10% by mass)
Lubricating agent: 1.6 parts by mass

(coating amount: 3.3 mg/m²)

(carnauba wax dispersion SELOSOL 524 (trade name), manufactured by Chukyo Yushi Co., Ltd., solid content 30% by mass)
Distilled water: added to make up the whole amount to 1000 parts by mass

<Film Formation for Electrode Pair>

The previously produced PET film was cut to A6 size, and this was used as the substrate 12.

On this substrate 12, the electrode pair 14 illustrated in FIG. 2(A) was produced by forming a 100 nm film of chromium and then a 200 nm film of gold by lamination by an ion plating method, using a metal mask formed by etching.

Each electrode was produced to have a length in the direction of arrangement of 10 mm and a length in the width direction of 6 mm. The interval in the direction of arrangement of the first electrode 14n and the second electrode 14p was set to 2 mm.

### Example 1

### Formation of Insulating Layer 18

On the substrate 12 having the electrode pair 14 formed thereon, a photosensitive epoxy resin (TB3114 (trade name), manufactured by ThreeBond Co., Ltd.) was printed using a screen printing machine (MT-550 (trade name), manufactured by Micro-tec Co., Ltd.) so as to have a length in the direction of arrangement of 3 mm, a length in the width direction of 8 mm, and a thickness of 15 μm, and the photosensitive epoxy resin was irradiated with UV light (amount of exposure: 1 J/cm²) using a UV irradiator (ECS-401GX (trade name), manufactured by Eye Graphics Co., Ltd.).

Printing of this photosensitive epoxy resin and UV irradiation was repeated three times, and thereby an insulating layer 18 based on a crosslinked polymer and having a thickness of 45 μm was formed as illustrated in FIG. 2(B). Therefore, in this example, the insulating layer 18 was formed by covering 0.5 mm of each edge on the inner side in the direction of arrangement of each electrode of the electrode pair 14 (coating width c=0.5 mm).

The shape of the insulating layer 18 thus formed was checked with a contact type film thickness meter, and it was confirmed that the insulating layer 18 had the shape illustrated in FIG. 2.

<Preparation of p-Type Thermoelectric Conversion Material Paste>

3 g of silica microparticles (JA-244 (trade name), manufactured by Jujo Chemical Co., Ltd.) were added to 27 g of a polystyrene having a degree of polymerization of 2000 (manufactured by Kanto Chemical Co., Inc.), and the mixture was dispersed with a two-roll mill that had been heated to 180° C. Thus, a silica-dispersed polystyrene was produced.

On the other hand, 10 ml of tetrahydronaphthalene (manufactured by Kanto Chemical Co., Inc.) was added to 25 mg of polyoctylthiophene (REGIORANDOM (trade name), manufactured by Sigma-Aldrich Co. LLC.), and a polythiophene solution was prepared using an ultrasonic cleaning machine (US-2 (trade name), manufactured by Iuchi Seieido Co., Ltd., power output 120 W, indirect irradiation).

To this polythiophene solution, 25 mg of single-layer carbon nanotubes (KH SWCNT HP (trade name), manufactured by KH Chemicals Co., Ltd., purity 80%) was added, and the mixture was ultrasonically dispersed at 30° C. for 30 minutes using a mechanical homogenizer (T10 basic ULTRA-TURRAX (trade name), manufactured by Ika Works, Inc.), an ultrasonic homogenizer (VC-750 (trade name), manufactured by Sonics & Materials, Inc.), and a taper microchip (probe diameter 6.5 mm), under the conditions of a power output of 50 W, direct irradiation, and a duty ratio of 50%. Thus, a dispersion liquid of carbon nanotubes was prepared.

Next, 1.0 g of a PC—Z type polycarbonate (PANLITE TS-2020 (trade name), manufactured by Teijin Chemicals, Ltd.) as a non-conjugated polymer and 1.0 g of the silica-dispersed polystyrene thus produced were added to the carbon nanotube dispersion liquid thus prepared, and the polymers were dissolved in a warm water bath at 50° C. Subsequently, the mixture was stirred for 15 minutes at a speed of rotation of 2200 rpm using a rotation and revolution type stirring apparatus (ARE-250 (trade name), manufactured by Thinky Inc.). Thus, a p-type thermoelectric conversion material paste was prepared.

<Formulation of p-Type Thermoelectric Conversion Layer 20p>

A metal mask made of SUS304 having an opening formed by laser processing and having a thickness of 1 mm was used, and the p-type thermoelectric conversion material paste thus prepared was poured onto the metal mask and was flattened with a squeegee.

Thereby, the p-type thermoelectric conversion material paste was printed on the second electrode 14p and the insulating layer 18 in the arrangement illustrated in FIG. 2(C).

The substrate 12 having the paste printed thereon was heated and dried on a hot plate at 80° C., and thereby, as illustrated in FIG. 2(C), a p-type thermoelectric conversion layer 20p having a length in the direction of arrangement of 5.5 mm, a length in the width direction of 6 mm, and a thickness of 150 μm was formed on the second electrode 14p and the insulating layer 18.

<Preparation of n-Type Thermoelectric Conversion Material Paste>

0.5 g of an aqueous solution of polyethyleneimine (solid content concentration 50 wt %, weight average molecular weight 750,000, manufactured by Sigma-Aldrich Co. LLC.) was mixed with 25 mg of single-layer carbon nanotubes (KH SWCNT HP (trade name), manufactured by KH Chemicals Co., Ltd., purity 80%), and the mixture was ultrasonically dispersed at 30° C. for 30 minutes using a mechanical homogenizer (T10 basic ULTRA-TURRAX (trade name), manufactured by Ika Works, Inc.), an ultrasonic homogenizer (VC-750 (trade name), manufactured by Sonics & Materials, Inc.), and a taper microchip (probe diameter 6.5 mm), under the conditions of a power output of 50 W, direct irradiation, and a duty ratio of 50%. Thus, a carbon nanotube dispersion liquid was prepared.

Next, 1.5 g of polyvinylpyrrolidone K-25 (manufactured by Wako Pure Chemical Industries, Ltd.) as a thickening agent was dissolved in the carbon nanotube dispersion liquid, and the mixture was stirred for a stirring time of 15 minutes at a speed of rotation of 2200 rpm using a rotation and revolution type stirring apparatus (ARE-250 (trade name), manufactured by Thinky Inc.). Thus, an n-type thermoelectric conversion material paste was prepared.

<Formation of Thermoelectric Conversion Layer of n-Type Semiconductor Material>

A metal mask made of SUS304 having an opening formed by laser processing and having a thickness of 1 mm was used, and the n-type thermoelectric conversion material paste thus prepared was poured onto the metal mask and was flattened with a squeegee. Thereby, the n-type thermoelectric conversion material paste was printed on the second electrode 14p and the insulating layer 18 in the arrangement illustrated in FIG. 2(D).

The substrate 12 having the paste printed thereon was heated and dried on a hot plate at 80° C., and thereby, as illustrated in FIG. 2(D), an n-type thermoelectric conversion layer 20n having a length in the direction of arrangement of 5.5 mm, a length in the width direction of 6 mm, and a thickness of 150 μm was formed on the first electrode 14n and the insulating layer 18.

Production of the thermoelectric conversion element 10 such as described above was carried out simultaneously for 10 units, such that the n-type thermoelectric conversion layer 20n and the p-type thermoelectric conversion layer 20p would be alternately arranged so as to obtain the arrangement illustrated in the plan view diagram of FIG. 5, and the second electrodes 14p and the first electrodes 14n of adjacent thermoelectric conversion elements 10 would be connected. Thus, the thermoelectric conversion module illustrated in the plan view diagram of FIG. 5 was produced.

### Example 2

A thermoelectric conversion element 10 was produced in the same manner as in Example 1, except that during the formation of the insulating layer 18; printing and UV irradiation were repeated five times, and thereby an insulating layer based on a crosslinked polymer and having a thickness of 72 μm was formed.

### Example 3

A thermoelectric conversion element 10 was produced in the same manner as in Example 1, except that during the formation of the insulating layer 18, printing and UV irradiation were repeated eight times, and thereby an insulating layer 18 based on a crosslinked polymer and having a thickness of 114 μm was formed.

### Example 4

A thermoelectric conversion element 24 was produced in the same manner as in Example 3, except that after the thermoelectric conversion layer 20 was formed, a connection wiring 26 was formed as illustrated in FIG. 3 by printing a silver paste (FN-333 (trade name), manufactured by Fujikura Kasei Co., Ltd.) on top of the thermoelectric conversion layer 20 composed of the p-type thermoelectric conversion layer 20p and the n-type thermoelectric conversion layer 20n, using a metal mask made of SUS304 having a thickness of 0.3 mm, and drying the silver paste for 1 hour on a hot plate at 80° C.

Meanwhile, the connection wiring 26 was formed at the center on top of the thermoelectric conversion layer 20, and had a length in the direction of arrangement of 8 mm, a length in the width direction of 4 mm, and a thickness of 20 μm.

### Example 5

### Preparation of p-Type Thermoelectric Conversion Material Paste

1.0 g of a PC—Z type polycarbonate (PANLITE TS-2020 (trade name), manufactured by Teijin Chemicals, Ltd.) as a non-conjugated polymer and 1.0 g of the silica-dispersed polystyrene thus produced were added to the carbon nanotube dispersion liquid thus prepared, and the polymers were dissolved in a warm water bath at 50° C. Subsequently, 0.1 g of phenethyltrimethoxysilane (manufactured by Geltest, Inc.) was dissolved therein, the mixture was stirred for 1 hour at room temperature, and the mixture was further stirred for 15 minutes at a speed of rotation of 2200 rpm using a rotation and revolution type stirring apparatus (ARE-250 (trade name), manufactured by Thinky Inc.). Thus, a p-type thermoelectric conversion material paste was prepared.

<Preparation of n-Type Semiconductor Material Paste>

After a carbon nanotube dispersion liquid was prepared in the same manner as in Example 1, 1.5 g of polyvinylpyrrolidone (K-25 (trade name), manufactured by Wako Pure Chemical Industries, Ltd.) as a thickening agent was dissolved in the carbon nanotube dispersion liquid, and then 0.1 g of 3-aminopropyltriethoxysilane (manufactured by Geltest, Inc.) was dissolved in the carbon nanotube dispersion liquid. Thereafter, the mixture was stirred for 1 hour at room temperature, and the mixture was further stirred for 15 minutes at a speed of rotation of 2200 rpm using a rotation and revolution type stirring apparatus (ARE-250 (trade name), manufactured by Thinky Inc.). Thus, an n-type thermoelectric conversion material paste was prepared.

A thermoelectric conversion element 10 was produced in the same manner as in Example 3, except that the p-type thermoelectric conversion layer 20p and the n-type thermoelectric conversion layer 20n were formed using the thermoelectric conversion material pastes described above.

### Example 6

A thermoelectric conversion element 10 was produced in the same manner as in Example 5, except that for the preparation of the p-type thermoelectric conversion material paste, 3-glycidoxypropyltrimethoxysilane (manufactured by Shin-Etsu Chemical Co., Ltd.) was used instead of phenethyltrimethoxysilane.

### Example 7

A thermoelectric conversion element 24 was produced in the same manner as in Example 5, except that after the thermoelectric conversion layer 20 was formed, a connection wiring 26 was formed, as illustrated in FIG. 3, by printing a silver paste (FN-333 (trade name), manufactured by Fujikura Kasei Co., Ltd.) on top of the thermoelectric conversion layer 20 composed of a p-type thermoelectric conversion layer 20p and an n-type thermoelectric conversion layer 20n by using a metal mask made of SUS304 having a thickness of 0.3 mm and flattening the silver paste with a squeegee, and drying the silver paste for 1 hour on a hot plate at 80° C.

Meanwhile, the connection wiring 26 was formed at the center on top of the thermoelectric conversion layer 20, and had a length in the direction of arrangement of 8 mm, a length in the width direction of 4 mm, and a thickness of 20 μm.

### Example 8

A thermoelectric conversion element 10a was produced in the same manner as in Example 7, except that the opening of the metal mask for forming a thermoelectric conversion layer that had been formed by laser processing was enlarged, and as illustrated in FIG. 1(C), the thermoelectric conversion layer 20 and the substrate 12 were brought into contact on both sides in the width direction of the electrode pair 14.

Meanwhile, the contact width o between the thermoelectric conversion layer 20 and the substrate 12 was set to 1 mm.

### Example 9

A thermoelectric conversion element 10 was produced in the same manner as in Example 1, except that during the formation of the insulating layer 18, printing and UV irradiation were repeated nine times, and thereby an insulating layer 18 based on a crosslinked polymer and having a thickness of 127 μm was formed.

### Example 10

A thermoelectric conversion element 10 was produced in the same manner as in Example 3, except that the insulating layer 18 was formed using EPO-TEK H70E (trade name (manufactured by Epoxy Technology, Inc.)), and the thickness of the insulating layer 18 was adjusted to 110 μm.

### Example 11

A thermoelectric conversion element 10 was produced in the same manner as in Example 1, except that during the formation of the insulating layer 18, printing and UV irradiation were repeated two times, and thereby an insulating layer 18 based on a crosslinked polymer and having a thickness of 29 μm was formed.

### Example 12

A thermoelectric conversion element 10 was produced in the same manner as in Example 1, except that during the formation of the insulating layer 18, printing and UV irradiation were repeated ten times, and thereby an insulating layer 18 based on a crosslinked polymer and having a thickness of 140 μm was formed.

### Comparative Example 1

A thermoelectric conversion module was produced in the same manner as in Example 1, except that the insulating layer 18 was not formed.

### Comparative Example 2

A thermoelectric conversion module was produced in the same manner as in Example 1, except that the size in the direction of arrangement of the insulating layer 18 was adjusted to 2 mm so that the insulating layer 18 did not cover the edges of the first electrode 14n and the second electrode 14p (coating width c=0 mm).

(Evaluation of Thermoelectric Conversion Module)

<Measurement of Thermal Conductivity of Insulating Layer>

A film having a thickness of 2 μm was formed on a Si substrate, gold was vapor deposited thereon, and then the thermal conductivity was measured by the 2ω method.

<Measurement of Heights of Insulating Layer and Thermoelectric Conversion Layer>

After an insulating layer 18 was formed, the level differences were measured using a contact type film thickness meter (XP-200 (trade name), manufactured by Ambios Technology, Inc.), and the thickness (height (apex)) of the insulating layer 18 from the substrate 12 was determined.

Furthermore, level differences at the joining interface between the n-type thermoelectric conversion layer 20n and the p-type thermoelectric conversion layer 20p were measured in the same manner as described above, and the thickness (height (apex)) of the thermoelectric conversion layer 20 from the electrodes was determined.

From the thicknesses of the two layers thus determined, the ratio between thicknesses of insulating layer 18/thermoelectric conversion layer 20 (t₁/t₂) was calculated.

<Evaluation of Amount of Power Generation>

The substrate side of a thermoelectric conversion module thus produced was mounted on a hot plate at 80° C., and a copper plate that was cooled to 10° C. by water cooling was installed on the thermoelectric conversion layer side. The open-electromotive voltage (V) generated at this time, and the internal resistance (R) were measured with a digital multimeter.

The amount of power generation=V²/R was calculated from the open-electromotive voltage and internal resistance R thus measured.

The amounts of power generation of various Examples that were normalized on the basis of the amount of power generation of Example 1 as “1.0” were calculated.

<Heat Cycle Test>

The ratio between the resistance values before and after a heat cycle test was calculated. Furthermore, the presence or absence of detachment was checked by visual inspection.

The heat cycle test was carried out by repeating five times a cycle of (1) increasing the temperature from 20° C. to 85° C. over 50 minutes, (2) maintaining the temperature at 85° C. for 10 minutes, (3) decreasing the temperature from 85° C. to 20° C. over 50 minutes, and (4) maintaining the temperature at 20° C. for 10 minutes, using a small-sized thermostatic chamber.

Evaluation was made based on the following criteria.

A: The change ratio of resistance was less than ±1%, and no detachment occurred.

B: The change ratio of resistance was ±1% or more but less than 2%, and no detachment occurred.

C: The change ratio of resistance was ±2% or more but less than 10%, no detachment occurred, and there was no problem for practical use.

D: Either the change ratio of resistance was ±10% or more, or detachment occurred.

The results are presented in the following table.

TABLE 1

| | Thermal | | Amount of | |
|---|---|---|---|---|
| | conductivity | | power | Heat |
| | [W/mk] | t₁/t₂ | generation | cycle |
| Example 1 | 0.25 | 0.3 | 1.0 | C |
| Example 2 | 0.25 | 0.49 | 1.4 | C |
| Example 3 | 0.25 | 0.76 | 1.6 | C |
| Example 4 | 0.25 | 0.78 | 1.8 | C |
| Example 5 | 0.25 | 0.74 | 1.6 | B |
| Example 6 | 0.25 | 0.76 | 1.6 | A |
| Example 7 | 0.25 | 0.76 | 2.0 | A |
| Example 8 | 0.25 | 0.72 | 1.9 | A |
| Example 9 | 0.25 | 0.85 | 1.4 | C |
| Example 10 | 0.9 | 0.73 | 1.3 | C |
| Example 11 | 0.25 | 0.19 | 0.7 | C |
| Example 12 | 0.25 | 0.93 | 0.9 | C |
| Comparative | — | — | 0.2 | D |
| Example 1 | | | | |
| Comparative | 0.25 | 0.3 | 0.6 | D |
| Example 2 | | | | |

As shown in Table 1, the thermoelectric conversion element of the invention has excellent heat generation characteristics and heat resistance (adhesive force of the thermoelectric conversion layer) compared to a thermoelectric conversion element that does not have an insulating layer 18, or a thermoelectric conversion element that has an insulating layer 18 but does not have the edges of the electrode pair covered by the insulating layer 18, and realizes a thermoelectric conversion element which corresponds to a π-type among those thermoelectric conversion elements using inorganic materials as the thermoelectric conversion material, by using organic thermoelectric conversion materials.

Specifically, according to the results of Examples 1 to 3 and 9, the amount of power generation changed depending on the ratio between thicknesses of insulating layer 18/thermoelectric conversion layer 20 (t₁/t₂), and the highest amount of power generation was obtained when the ratio was 0.76.

According to the results of Examples 3 and 4 and the results of Examples 5 and 7, higher amounts of power generation were obtained in Examples 4 and 7 in which the connection wiring 26 was formed using a silver paste. Results suggesting that the amount of power generation increases due to the effect that the resistance value is decreased at the joined part between the p-type thermoelectric conversion layer and the n-type thermoelectric conversion layer by forming the connection wiring 26 with a silver paste, were obtained.

According to the results of Examples 5 and 6, results in which the resistance to heat cycling was increased by crosslinking the thermoelectric conversion layer, were obtained.

From the results obtained above, the effects of the present invention are obvious.

### EXPLANATION OF REFERENCES

10, 10a, 24: thermoelectric conversion element
12: substrate
14: electrode pair
14n: first electrode
14p: second electrode
18: insulating layer
20: thermoelectric conversion layer
20n: n-type thermoelectric conversion layer
20p: p-type thermoelectric conversion layer
26: connection wiring

What is claimed is:

1. A thermoelectric conversion element comprising:
a substrate;
a pair of electrodes formed to be arranged apart from each other on the surface of the substrate;
an insulating layer formed between the pair of electrodes so as to be in contact with the substrate and to cover the edges on the sides where the pair of electrodes face each other; and
a thermoelectric conversion layer composed of a p-type thermoelectric conversion layer containing an organic p-type thermoelectric conversion material, which is formed to cover at least a portion of one of the pair of electrodes, and an n-type thermoelectric conversion layer containing an organic n-type thermoelectric conversion material, which is formed to cover at least a portion of the other one of the pair of electrodes,
wherein the p-type thermoelectric conversion layer and the n-type thermoelectric conversion layer have a separation region in which the thermoelectric conversion layers are arranged apart by the insulating layer, and a contact region in which the thermoelectric conversion layers are joined to each other in a part above the insulating layer.

2. The thermoelectric conversion element according to claim 1, wherein the thermal conductivity of the insulating layer is 1 W/(m·K) or less.

3. The thermoelectric conversion element according to claim 1, wherein the substrate is formed from an organic material.

4. The thermoelectric conversion element according to claim 1, wherein the insulating layer has a circular arc-shaped top surface.

5. The thermoelectric conversion element according to claim 1, wherein the ratio between thicknesses of the insulating layer and the thermoelectric conversion layer satisfies the condition:
“insulating layer/thermoelectric conversion layer=0.3 to 0.9”.

6. The thermoelectric conversion element according to claim 1, further comprising, on the p-type thermoelectric conversion layer and the n-type thermoelectric conversion layer, an electrode for connection that is brought into contact with the two thermoelectric conversion layers.

7. The thermoelectric conversion element according to claim 1, wherein the p-type thermoelectric conversion layer and the n-type thermoelectric conversion layer each contain carbon nanotubes and a binder.

8. The thermoelectric conversion element according to claim 1, wherein at least one of the p-type thermoelectric conversion layer and the n-type thermoelectric conversion layer is formed such that a portion thereof is brought into contact with the substrate.

9. A thermoelectric conversion module comprising a plurality of the thermoelectric conversion elements connected in series, formed by
arranging the thermoelectric conversion elements according to claim 1 to be apart from each other such that the p-type thermoelectric conversion layers and the n-type thermoelectric conversion layers are alternately arranged, and
connecting the electrodes covered by the p-type thermoelectric conversion layers of adjacent thermoelectric conversion elements, to the electrodes covered by the n-type thermoelectric conversion layers of adjacent thermoelectric conversion elements.
